(19) United States
(12) Patent Application Publication
(10) Pub. No.: US 2007/0283879 A1
(43) Pub. Date: Dec. 13, 2007

(54) Thermally driven externally circulating hydrothermal crystallization vessel

(76) Inventors: Minel J. Braun, Akron, OH (US); Hongmin Li, Akron, OH (US)

Correspondence Address: ROETZEL AND ANDRESS, 222 SOUTH MAIN STREET, AKRON, OH, 44308, US

(21) Appl. No.: 11/796,685

(22) Filed: Apr. 27, 2007

Related U.S. Application Data
(60) Provisional application No. 60/795,884, filed on Apr. 28, 2006.

(51) Int. Cl. C30B 7/10

(52) U.S. Cl. 117/48; 422/253

(57) ABSTRACT

The present invention generally relates to apparatuses for crystal growth. More specifically, the present invention relates to an apparatus that improves the hydrothermal growth of crystals, via the use of one or more thermally driven circulation loops. In one embodiment, the present invention provides crystal growth apparatuses that contain an improved crystal growth environment thereby yielding improved quality control and crystal uniformity.

### RELATED APPLICATION DATA

This application claims priority to previously filed U.S. Provisional Application No. 60/795,884, filed on Apr. 28, 2006, entitled “Thermally Driven Externally Circulating Hydrothermal Crystallization Vessel.” The above-identified provisional patent application is hereby incorporated by reference in its entirety.

### FIELD OF THE INVENTION

The present invention generally relates to apparatuses for crystal growth. More specifically, the present invention relates to an apparatus that improves the hydrothermal growth of crystals, via the use of one or more thermally driven circulation loops. In one embodiment, the present invention provides crystal growth apparatuses that contain an improved crystal growth environment thereby yielding improved quality control and crystal uniformity.

### BACKGROUND OF THE INVENTION

Crystals have various applications, some of which include, but are not limited to, electronic applications, chemical reaction applications, and medical applications. For example, some crystals' piezoelectric properties allow single crystals to be used in surface acoustic wave devices and highly accurate frequency control instrumentation. Crystals are also used for camera lenses due to their high transparencies and other optical properties. In certain chemical reactions, crystals are used as substrate material because of their particular crystal lattice structure. These applications generally require high quality crystals possessing minimal lattice structural defects and a low concentration of one or more undesirable materials.

In some instances, when a crystal is needed for a particular application, natural crystals can be used. However, natural crystals tend to suffer from quality as well as availability issues. Given these issues, most crystals in widespread use today are synthetic or “cultured” crystals.

In general, there are three well-established crystal growth methods. They are: crystal growth from melt, crystal growth from vapor, and crystal growth from solution. In the crystal growth from melt and/or crystal growth from vapor methods, the growth temperature is elevated to at least the melting point of the material from which the crystals are to be grown. However, in some instances a melt and/or vapor phase crystal growth method can not be utilized as the material from which the crystals are to be grown changes lattice structures upon cooling. In other words, one or more chemical reactions may take place at a temperature lower than the melting point of the material from which the crystals are to be grown. This may cause/lead to unwanted changes in the crystal lattice structure as the crystalline structures cool.

The third growth method is a solution-based growth method in which, as the name implies, crystals are grown in a solution. Hydrothermal growth is one such solution growth method of crystals. Such a method is advantageous in that it reduces and/or eliminates some of the problems associated with the crystal growth from melt and/or crystal growth from vapor methods (e.g., heating and cooling problems leading to crystal lattice structural changes).

During hydrothermal growth, a raw material is dissolved into solution in one chamber of a dual-chambered crystal growth apparatus. In the second chamber of the dual-chambered crystal growth apparatus, crystals are produced/grown as the raw material precipitates out of solution and deposits onto seed crystals located in the second chamber. In one instance, the crystal growth process is driven by a difference in the solubility of the raw material in solution in the first and second chambers of the dual-chambered crystal growth apparatus. In one case, the solubility of the raw material in each of the first and second chambers of the dual-chambered crystal growth apparatus correlates to the temperature of the solution in each chamber. Thus, by varying the temperature in each chamber, one of ordinary skill in the art is able to control crystal growth.

Due in part to the above, the hydrothermal crystal growth method tends to utilize an operational temperature, or crystal growth temperature, that is usually less than the melting point of the raw material. Accordingly, the hydrothermal crystal growth method can yield crystals having improved uniformity (e.g., improved uniformity in shape, size, lattice structure, impurity concentration, etc.).

In order to achieve reasonable crystal growth rates in the above method, the growth conditions, including temperature and pressure, are selected to obtain a high solubility of the raw material. Usually, the pressure at which crystal growth procedures are conducted is greater than normal atmospheric pressure (i.e., 500 to 2000 atmospheric pressure and 200 to 700° C.). Thus, in increased pressure situations, a hydrothermal crystal growth process must be carried out in a closed pressure vessel or container, and can not rely on the use of one or more pumps to move fluid about the pressure vessel/container. Such pumps need to be connected to the outside of the growth vessel via holes in the growth vessel wall (i.e., power lines or rotating shafts). With such holes in the growth vessel wall, higher pressures in the growth vessel lead to high stress concentration around said holes. Fatigue and solution leakage thus becomes a common and difficult problem to solve. In lower pressure situations, using a pump remains feasible for fluid movement.

One solution regarding problems associated with pressurized crystal growth processes previously investigated is the use of temperature driven crystal growth processes. The aim of a temperature driven process is to establish a flow of the raw material laden solution through a crystal growth apparatus such as an autoclave. Current industry autoclaves are closed cylindrical enclosures separated by a baffle into two separate chambers. One chamber is designated the dissolving chamber; while the other is designated the growth chamber. The raw material laden solution is transported from the dissolving chamber to the growth chamber by flowing the solution through a baffle opening. The baffle is used to separate the different temperature zones that exist in the dissolving chamber and the growth chamber.

This crystal growth apparatus setup suffers from a number of drawbacks including, but not limited to, a lower crystal growth rate near the baffle. This is generally caused by a localized high temperature zone that is located near to and/or adjacent to the baffle in the growth chamber. Another drawback is that the crystal growth rate in the upper portion of the growth chamber can be lower due to a depletion of raw material laden solution. Thus, the devices of the prior art suffer from a number of drawbacks that limit their effectiveness in the growth of high quality crystals (e.g., crystal that possess more uniform properties).

### SUMMARY OF THE INVENTION

The present invention generally relates to apparatuses for crystal growth. More specifically, the present invention relates to an apparatus that improves the hydrothermal growth of crystals, via the use of one or more thermally driven circulation loops. In one embodiment, the present invention provides crystal growth apparatuses that contain an improved crystal growth environment thereby yielding improved quality control and crystal uniformity.

In one embodiment the invention discloses a crystal growth apparatus comprising: (a) a crystal growth vessel, the crystal growth vessel comprising: an upper chamber, a lower chamber, and at least one baffle means, the baffle means being located within the crystal growth vessel so as to form a boundary between the upper and lower chambers, wherein the upper and lower chambers of the crystal growth vessel each contain at least one opening designed to receive a circulating conduit and wherein the crystal growth vessel is designed to hold a crystal growth solution; (b) a circulating loop formed from the circulating conduit, wherein the circulating loop connects the upper chamber of the crystal growth vessel to the lower chamber of the crystal growth vessel; and (c) at least one heating means, wherein the at least one heating means independently provides heat to each of the upper chamber of the crystal growth vessel, the lower chamber of the crystal growth vessel, and the circulating loop.

In another embodiment the crystal growth apparatus comprises a crystal growth apparatus comprising: (a) a crystal growth vessel, the crystal growth vessel comprising: an upper chamber, a lower chamber, and at least one baffle means, the baffle means being located within the crystal growth vessel so as to form a boundary between the upper and lower chambers, wherein the upper and lower chambers of the crystal growth vessel each contain at least one opening designed to receive a circulating conduit and wherein the crystal growth vessel is designed to hold a crystal growth solution; (b) a circulating loop formed from the circulating conduit, wherein the circulating loop connects the upper chamber of the crystal growth vessel to the lower chamber of the crystal growth vessel; (c) at least one heating means, wherein the at least one heating means independently provides heat to each of the upper chamber of the crystal growth vessel, the lower chamber of the crystal growth vessel, and the circulating loop; and (d) at least one control means designed to selectively control the at least one heating means in order to create a thermodynamic gradient wherein the thermodynamic gradient moves the solution though the apparatus.

In still another embodiment the present invention discloses a method for growing crystals comprising the steps of: (A) providing at least one crystal growth apparatus, the crystal growth apparatus comprising: (i) a crystal growth vessel with an upper chamber, a lower chamber, and at least one baffle means, the baffle means being located within the crystal growth vessel so as to form a boundary between the upper and lower chambers, wherein the upper and lower chambers of the crystal growth vessel each contain at least one opening designed to receive a circulating conduit and wherein the crystal growth vessel is designed to hold a crystal growth solution; (ii) a circulating loop formed from the circulating conduit, wherein the circulating loop connects the upper chamber of the crystal growth vessel to the lower chamber of the crystal growth vessel; (iii) at least one heating means, wherein the at least one heating means independently provides heat to each of the upper chamber of the crystal growth vessel, the lower chamber of the crystal growth vessel, and the circulating loop; (B) placing a crystal forming raw material in the crystal growth vessel; (C) placing seed crystals in the crystal growth vessel; (D) placing a solution in the crystal growth vessel wherein the solution is capable of dissolving the crystal forming raw material; and (E) selectively controlling the temperature in the upper and lower chambers of the crystal growth vessel and the circulating loop in order to create a thermodynamic temperature gradient thereby causing the crystal growth solution to circulate through the crystal growth apparatus whereby crystals are caused to grow on the seed crystals as a result thereof.

### BRIEF DESCRIPTION OF THE DRAWINGS

FIG. 1 is a schematic illustration of a crystal growth apparatus according to one embodiment of the present invention;

FIG. 2 is a schematic illustration of a crystal growth apparatus according to another embodiment of the present invention;

FIG. 3 is an illustration detailing the flow in a conventional hydrothermal autoclave and the flow in a crystal growth vessel according to one embodiment of the present invention; and

FIG. 4 is a schematic showing embodiments of the crystal growth apparatus detailing a pump assisting fluid flow.

### DETAILED DESCRIPTION OF THE INVENTION

The present invention generally relates to apparatuses for crystal growth. More specifically, the present invention relates to an apparatus that improves the hydrothermal growth of crystals, via the use of one or more thermally driven circulation loops. In one embodiment, the present invention provides crystal growth apparatuses that contain an improved crystal growth environment thereby yielding improved quality control and crystal uniformity.

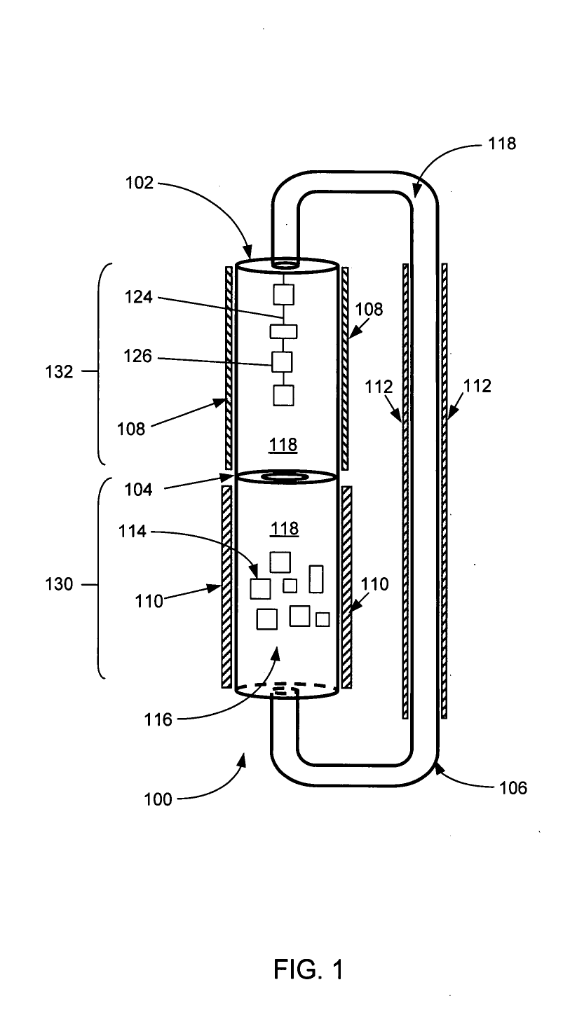

Turning to the Figures, FIG. 1 discloses a crystal growth apparatus according to one embodiment of the present invention. In the embodiment of FIG. 1, crystal growth apparatus 100 comprises a cylindrical shaped autoclave 102, a baffle 104, circulating loop 106, and heating means (e.g., heaters) 108, 110 and 112. It should be noted that the present invention is not limited to an autoclave 102 having a cylindrical shape. Rather, any suitable geometric shape can be utilized for autoclave 102 in the present invention, so long as the shape of autoclave 102 permits the circulation of raw material laden crystal forming solution.

In one embodiment, autoclave 102 is formed from any material that is capable of withstanding increased pressures and/or temperatures. In this embodiment, autoclave 102 should be capable of withstanding a pressure of at least about 5 atmospheres, at least about 500 atmospheres, or even greater than about 2000 atmospheres. The material that is used to form autoclave 102 should be able to withstand a temperature of at least about 100° C., at least about 300° C., at least about 600° C., or even at least about 1000° C. In one embodiment 102 is formed from steel or stainless-steel. In another embodiment, autoclave 102 can be formed from any suitable metal, alloy, amalgam, ceramic, plastic, glass, fiberglass, or combination of two or more thereof.

The operation of apparatus 100 will now be explained in detail. Initially, small pieces of raw material 114 are loaded into autoclave 102. Prior to sealing autoclave 102 on its top, the central chamber 116 of autoclave 102 is completely filled with a suitable solution 118 so as to eliminate any air pockets in the interior of autoclave 102. Optionally, apparatus 100 can include an air or solution escape valve that permits one to bleed off any unwanted air or solution from apparatus 100 to maintain a constant pressure in autoclave 102.

In another embodiment, autoclave 102 is not completely filled with solution 118. In this embodiment, air fills the reminder of autoclave 102. At higher pressures and/or temperatures the air contained in autoclave 102 dissolves into solution 118 resulting in a single phase solution filling both chambers of autoclave 102.

As would be apparent to one of ordinary skill in the art, solution 118 is selected depending upon the nature/chemical composition of the crystals to be grown in apparatus 100. Such factors to consider include, but are not limited to, the solubility of the crystal growth raw material in solution 118, stability of solution 118 at the operational temperature and/or pressure, and the viscosity of solution 118. In one embodiment, solution 118 can be selected as a single or combination of solutions from Group IA or IIA metal hydroxide solutions (e.g., sodium hydroxide or potassium hydroxide) or Group IA or IIA metal carbonate solutions (e.g., sodium carbonate or potassium carbonate), or other inorganic salt solutions (e.g., potassium sulfate or aluminum sulfate).

Once autoclave 102 has been “loaded” with small pieces of raw material 114 and solution 118, autoclave 102 is sealed. Once autoclave 102 is sealed, baffle 104 serves to substantially separate lower chamber 120 of autoclave 102 from upper chamber 122 of autoclave 102. Baffle 104 operates as a means for fluid flow control. A rack 124 located in upper chamber 122 holds a collection of seed crystals 126 in autoclave 102. Heating elements 108 surround the exterior of upper chamber 122 of autoclave 102, while heating elements 110 surround the exterior of lower chamber 120 of autoclave 102. In one embodiment, heating elements 108 and 110 are cylindrical electrical heating elements and surround substantially all of the exterior of lower and upper chambers 120 and 122, respectively. In another embodiment, heating elements 108 and 110 are not limited to cylindrically-shaped electrical heating elements and can instead be formed in any suitable shape that can be placed on or near the exterior surface of autoclave 102.

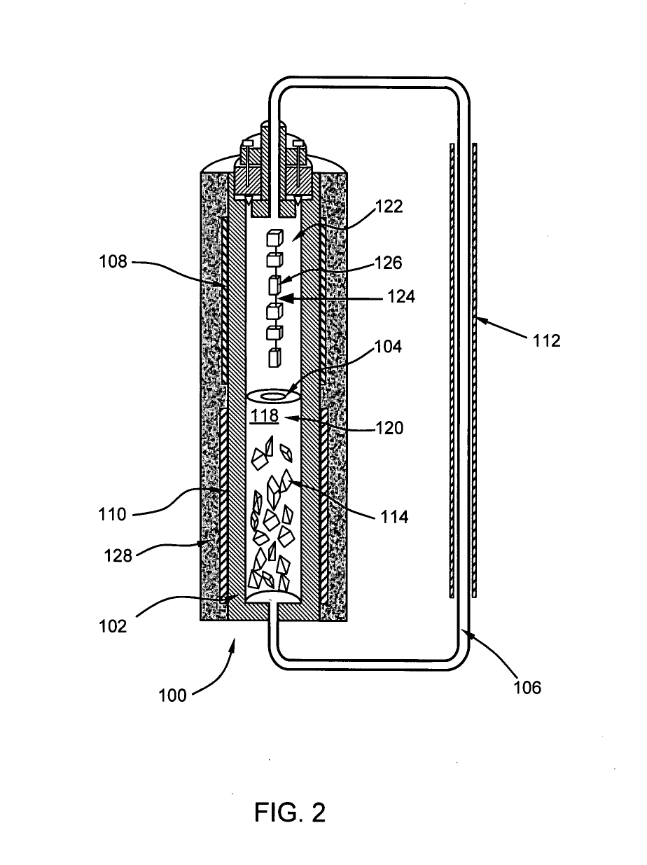

It should be noted that heaters 108 and 110 are able to be controlled independently in order to create a temperature difference and/or gradient between the lower and upper chambers 120 and 122, respectively, of autoclave 102. In one embodiment, the exterior surface of autoclave 102 and heating elements 108 and 110 can be covered by an insulation layer 128 (see FIG. 2). In one embodiment, insulation layer 128 can be selected from any suitable insulating material that can withstand the temperatures being used in autoclave 102. Such materials include, but are not limited to, fiberglass, wool, cotton, paper, cardboard, and/or a ceramic compound.

In another embodiment the heaters 108, 110, and 112 can be controlled via zone heating. Such a setup would employ two or more zones within the upper chamber 122, lower chamber 120 and/or the circulating loop 106. Such an arrangement of two or more zones in one or more of the upper chamber 122, lower chamber 120 and the circulating loop 106 allowing greater control and flexibility over the flow-rate and characteristics of solution 118.

Optionally, apparatus 100 also incorporates temperature controls, temperature sensors and adequate shielding to minimize any possible explosion hazard. The temperature controls and sensors also acting as a means to selectively control the heating means and create a thermodynamic gradient.

Turning to baffle 104, baffle 104 serves to create two localized temperature zones in autoclave 102. As would be apparent to one of ordinary skill in the art, a lower temperature zone 130 exists in lower autoclave chamber 120, while a higher temperature zone 132 exists in upper autoclave chamber 122.

The crystal growing method of the present invention will now be explained in detail. The crystal growth technique/method of the present invention utilizes crystal seeds 126, high purity raw material 114, and a high purity solution 118 that is capable of carrying in solution raw material 114. The crystal seeds 126 in one embodiment being “high perfection” crystal seeds.

In order to create a flow between lower and upper chambers 120 and 122, respectively, of autoclave 102, a circulating loop 106 is connected to both the lower and upper chambers 120 and 122, respectively, of autoclave 102. In one embodiment, circulating loop 106 is connected to the lower and upper ends of autoclave 102 (see FIG. 1). Circulating loop 106 is surrounded by heating means 112 (e.g., a cylindrically-shaped electrical heating element). Again, heating means 112 is not limited to a cylindrically-shaped electrical heating element, instead heating means 112 can be any suitable heating means as described above in relation to heating means 108 and 110.

In one embodiment, the temperature in upper chamber 122 of autoclave 102 is set T₁, the temperature in lower chamber 120 of autoclave 102 is set T₂, where T₁<T₂. In this embodiment, circulating loop 106 is set at a temperature near to or equal to T₁ in order to create a solution flow from lower chamber 120 through circulating loop 106 into upper chamber 122 where raw material laden solution 118 contributes to the further growth of seed crystals 126. Then, raw material depleted solution 118 flows through baffle 104 and into lower chamber 120 as a means of “picking up” more raw material from raw material supply 114.

In another embodiment, the temperature in upper chamber 122 of autoclave 102 is set T₁, the temperature in lower chamber 120 of autoclave 102 is set T₂, where T₂<T₁. In this embodiment, circulating loop 106 is set at a temperature near to or equal to T₁ in order to create a solution flow from upper chamber 122 through circulating loop 106 into lower chamber 120 where raw material depleted solution 118 “picks-up” more raw material from raw material supply 114. The raw material laden solution 118 then passes through baffle 104 and into upper chamber 122 where the raw material laden solution 118 contributes to the further growth of seed crystals 126.

Although FIGS. 1 through 3 show lower chamber 120 and upper chamber 122 to be approximately equal in volume, this is not a pre-requisite of the present invention. Instead, lower and upper chambers 120 and 122, respectively, can be, independent of one another, any size or shape.

With regard to circulating loop 106, the interior diameter of circulating loop 106 should be chosen so as to achieve the desired flow rate between the upper and lower chambers of autoclave 102. Where autoclave 102 is cylindrical in shape, circulating loop 106 can be a pipe having an internal diameter that at least about one tenth of the interior diameter of autoclave 102.

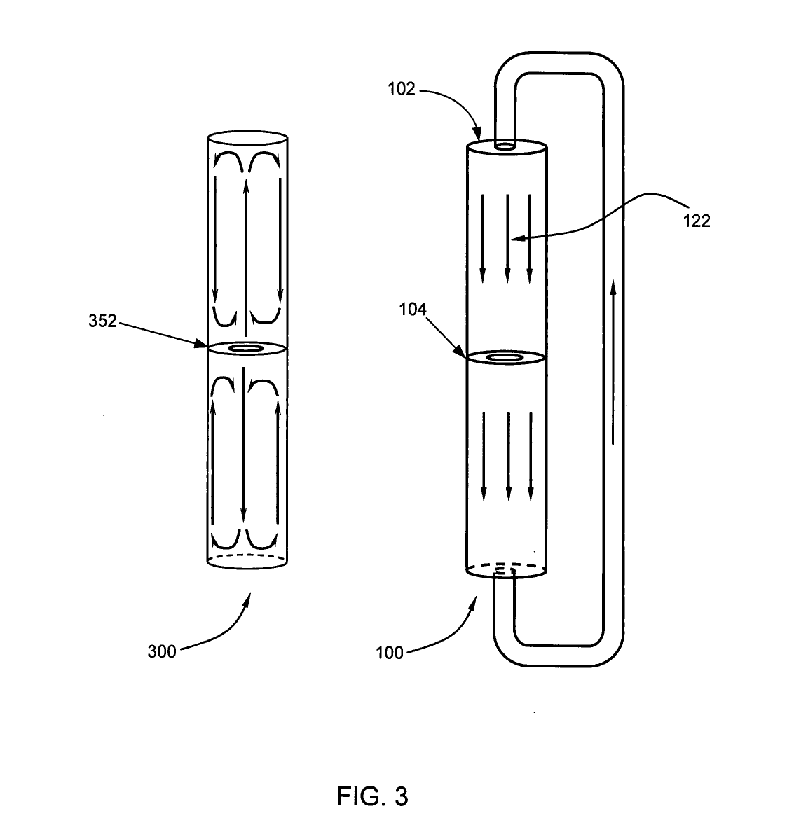

FIG. 3 illustrates a flow structure in a convectional hydrothermal autoclave 300 and a flow structure in an autoclave 100 according to the present invention. In autoclave 300, the two chambers each possess a substantially discrete flow with only a portion of each flow passing through baffle 352. As can be seen in FIG. 3, the flow in the present invention is unidirectional throughout autoclave 100. Velocity and temperature eddies can still exist within autoclave 102, but are generally reduced to a minimum if present. As a result, the present invention enables a unidirectional flow across baffle 104 and as a results promotes a more homogenous growth environment in upper chamber 122. This in turn permits the production of improved crystals.

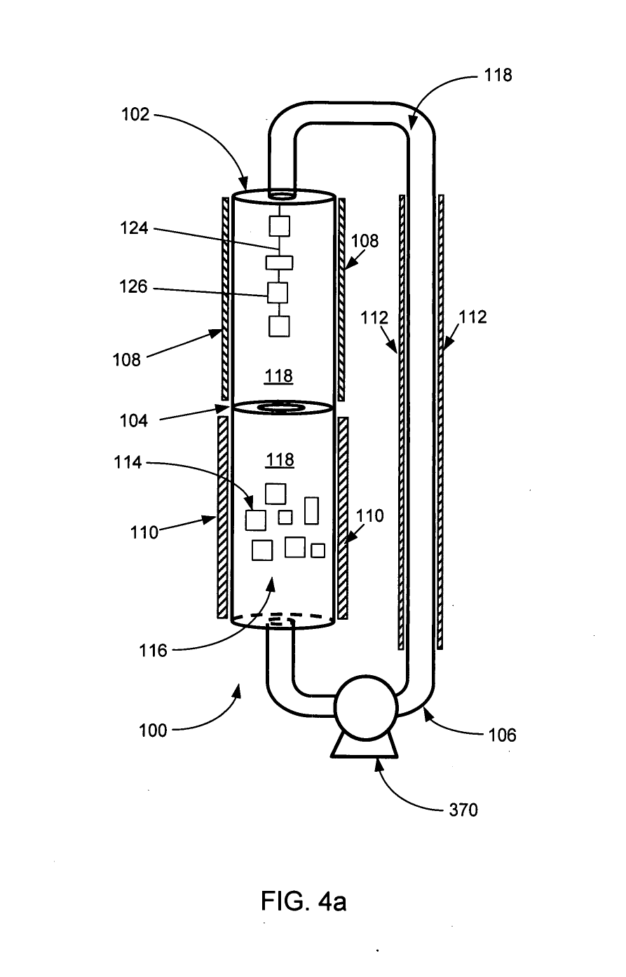

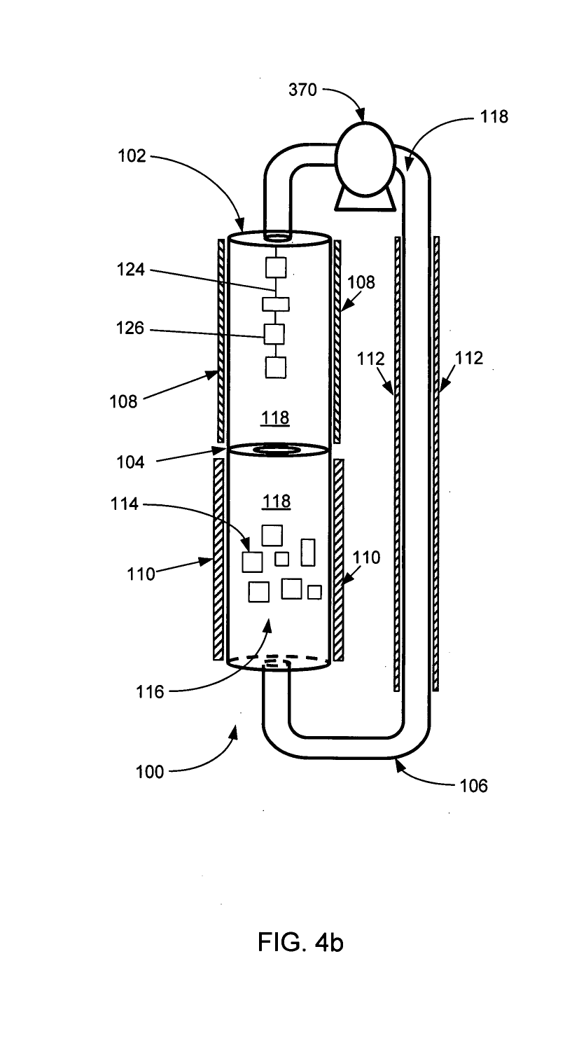

FIGS. 4a and 4b detail embodiments of the present invention which utilize at least one pump 370 as part of circulation loop 106. Such an embodiment typically involves a lower pressure setup whereby one desires to increase, or control, the flow rate of a solution through circulation loop 106. In such situations, solution 118 flows due to the combination of pump 370 and the natural convection described previously. In another variation of this embodiment, pump 370 alone causes the circulation of solution 118 through circulation loop 106. In these embodiments, pump 370 can be located at or near the inlet of the lower chamber 120 to act as a pressure supply pump for the fluid. In another embodiment, pump 370 can be located as a suction pump at or near the exit of upper chamber 122. In still another embodiment, the location of pump 370 is not limited to any one specific place. Rather, pump 370 can be placed in any suitable position so long as pump 370 is in fluid communication with circulating loop 106.

As would be recognized by one of skill in the art, the crystal growth chamber in the present invention can be either the upper and lower chamber. Accordingly, the designations used herein are only for convenience and the present invention is not limited to only the layout orientation disclosed herein. Furthermore, although the crystal growth apparatus of the present invention is shown with two chambers in the attached Figures, the present invention is not limited thereto. Rather, a crystal growth apparatus according to the present invention can have three, four, five, or more chambers, with each chamber being somewhat isolated from every other chamber by a baffle or some other suitable partition. In addition the circulating loop is shown as a standard recirculation loop with a simple return. The present invention is not limited thereto as the re-circulating loop may employ any number of bends, turns, and/or devices to aid material flow or change material characteristics.

Although the invention has been described in detail with particular reference to certain embodiment detailed herein, other embodiments can achieve the same results. Variations and modifications of the present invention will be obvious to those skilled in the art and the present invention is intended to cover in the appended claims all such modifications and equivalents.

What is claimed is:

1. A crystal growth apparatus comprising:
(a) a crystal growth vessel, the crystal growth vessel comprising:
an upper chamber;
a lower chamber; and
at least one baffle means, the baffle means being located within the crystal growth vessel so as to form a separation between the upper and lower chambers, wherein the upper and lower chambers of the crystal growth vessel each contain at least one opening designed to receive a circulating conduit and wherein the crystal growth vessel is designed to hold a crystal growth solution;
(b) a circulating loop formed from the circulating conduit, wherein the circulating loop connects the upper chamber of the crystal growth vessel to the lower chamber of the crystal growth vessel; and
(c) at least one heating means, wherein the at least one heating means independently provides heat to each of the upper chamber of the crystal growth vessel, the lower chamber of the crystal growth vessel, and the circulating loop.

2. The apparatus of claim 1, wherein the crystal growth vessel is formed from any suitable metal, metal alloy, metal amalgam, ceramic, plastic, glass, fiberglass, or combination of two or more thereof.

3. The apparatus of claim 2, wherein the crystal growth vessel is formed from steel or stainless-steel.

4. The apparatus of claim 1, wherein the circulating loop is formed from any suitable metal, metal alloy, metal amalgam, ceramic, plastic, glass, fiberglass, or combination of two or more thereof.

5. The apparatus of claim 4, wherein the circulating loop is formed from steel or stainless-steel.

6. The apparatus of claim 1, wherein the at least one heating means is formed from one or more electric heating elements.

7. The apparatus of claim 1, wherein at least one crystal forming material is soluble in the solution.

8. The apparatus of claim 1, wherein the upper chamber of the crystal growth vessel is the chamber in which crystal growth occurs and the upper chamber further comprises at least one seed crystal placed therein prior to use thereof.

9. The apparatus of claim 1, wherein the lower chamber of the crystal growth vessel is the chamber in which the raw material for crystal growth occurs and the lower chamber further comprises at least one seed crystal placed therein prior to use thereof.

10. The apparatus of claim 1 further comprising an insulating means, wherein the insulating means surrounds at least a portion of the exterior surface of the crystal growth vessel.

11. The apparatus of claim 1 wherein the circulating loop further includes a pump.

12. The apparatus of claim 1 wherein the at least one heating means comprises at least two independently controlled heating zones in the upper chamber.

13. The apparatus of claim 1 wherein the at least one heating means comprises at least two independently controlled heating zones in the lower chamber.

14. The apparatus of claim 1 wherein the at least one heating means comprises at least two independently controlled heating zones in the circulating loop.

15. A crystal growth apparatus comprising:
(a) a crystal growth vessel, the crystal growth vessel comprising:
an upper chamber;
a lower chamber; and
at least one baffle means, the baffle means being located within the crystal growth vessel so as to form a separation between the upper and lower chambers, wherein the upper and lower chambers of the crystal growth vessel each contain at least one opening designed to receive a circulating conduit and wherein the crystal growth vessel is designed to hold a crystal growth solution;
(b) a circulating loop formed from the circulating conduit, wherein the circulating loop connects the upper chamber of the crystal growth vessel to the lower chamber of the crystal growth vessel;
(c) at least one heating means, wherein the at least one heating means independently provides heat to each of the upper chamber of the crystal growth vessel, the lower chamber of the crystal growth vessel, and the circulating loop; and
(d) at least one control means designed to selectively control the at least one heating means in order to create a thermodynamic gradient wherein the thermodynamic gradient moves the solution though the apparatus.

16. The apparatus of claim 15, wherein the crystal growth vessel is formed from any suitable metal, metal alloy, metal amalgam, ceramic, plastic, glass, fiberglass, or combination of two or more thereof.

17. The apparatus of claim 16, wherein the crystal growth vessel is formed from steel or stainless-steel.

18. The apparatus of claim 15, wherein the circulating loop is formed from any suitable metal, metal alloy, metal amalgam, ceramic, plastic, glass, fiberglass, or combination of two or more thereof.

19. The apparatus of claim 18, wherein the circulating loop is formed from steel or stainless-steel.

20. The apparatus of claim 15, wherein the at least one heating means is formed from one or more electric heating elements.

21. The apparatus of claim 15, wherein at least one crystal forming material is soluble in the solution.

22. The apparatus of claim 15, wherein the upper chamber of the crystal growth vessel is the chamber in which crystal growth occurs and the upper chamber further comprises at least one seed crystal placed therein prior to use thereof.

23. The apparatus of claim 15, wherein the lower chamber of the crystal growth vessel is the chamber in which the raw material for crystal growth occurs and the lower chamber further comprises at least one seed crystal placed therein prior to use thereof.

24. The apparatus of claim 15 further comprising an insulating means, wherein the insulating means surrounds at least a portion of the exterior surface of the crystal growth vessel.

25. The apparatus of claim 15 wherein the circulating loop further includes a pump.

26. The apparatus of claim 15 wherein the at least one heating means comprises at least two independently controlled heating zones in the upper chamber.

27. The apparatus of claim 15 wherein the at least one heating means comprises at least two independently controlled heating zones in the lower chamber.

28. The apparatus of claim 15 wherein the at least one heating means comprises at least two independently controlled heating zones in the circulating loop.

29. A method for growing crystals comprising the steps of:
(A) providing at least one crystal growth apparatus, the crystal growth apparatus comprising:
(1) a crystal growth vessel with:
an upper chamber;
a lower chamber; and
at least one baffle means, the baffle means being located within the crystal growth vessel so as to form a separation between the upper and lower chambers, wherein the upper and lower chambers of the crystal growth vessel each contain at least one opening designed to receive a circulating conduit and wherein the crystal growth vessel is designed to hold a crystal growth solution;
(2) a circulating loop formed from the circulating conduit, wherein the circulating loop connects the upper chamber of the crystal growth vessel to the lower chamber of the crystal growth vessel;
(3) at least one heating means, wherein the at least one heating means independently provides heat to each of the upper chamber of the crystal growth vessel, the lower chamber of the crystal growth vessel, and the circulating loop;
(B) placing a crystal forming raw material in the crystal growth vessel;
(C) placing seed crystals in the crystal growth vessel;
(D) placing a solution in the crystal growth vessel, wherein the solution is capable of dissolving the crystal forming raw material; and
(E) selectively controlling the temperature in the upper and lower chambers of the crystal growth vessel and the circulating loop in order to create a thermodynamic temperature gradient thereby causing the crystal growth solution to circulate through the crystal growth apparatus whereby crystals are caused to grow on the seed crystals as a result thereof.

30. The method of claim 29, wherein the crystal growth vessel is formed from any suitable metal, metal alloy, metal amalgam, ceramic, plastic, glass, fiberglass, or combination of two or more thereof.

31. The method of claim 30, wherein the crystal growth vessel is formed from steel or stainless-steel.

32. The method of claim 29, wherein the circulating loop is formed from any suitable metal, metal alloy, metal amalgam, ceramic, plastic, glass, fiberglass, or combination of two or more thereof.

33. The method of claim 32, wherein the circulating loop is formed from steel or stainless-steel.

34. The method of claim 29, wherein the at least one heating means is formed from one or more electric heating elements.

35. The method of claim 29, wherein at least one crystal forming material is soluble in the solution.

36. The method of claim 29, wherein the upper chamber of the crystal growth vessel is the chamber in which crystal growth occurs and the upper chamber further comprises at least one seed crystal placed therein prior to use thereof.

37. The method of claim 29, wherein the lower chamber of the crystal growth vessel is the chamber in which the raw material for crystal growth occurs and the lower chamber further comprises at least one seed crystal placed therein prior to use thereof.

38. The method of claim 29 further comprising an insulating means, wherein the insulating means surrounds at least a portion of the exterior surface of the crystal growth vessel.

39. The method of claim 29 further comprising at least one control means designed to selectively control the at least one heating means in order to create a thermodynamic gradient.

40. The method of claim 29 wherein circulating the crystal growth solution includes the use of a pump.

41. The method of claim 29 wherein the at least one heating means comprises at least two independently controlled heating zones in the upper chamber.

42. The method of claim 29 wherein the at least one heating means comprises at least two independently controlled heating zones in the lower chamber.

43. The method of claim 29 wherein the at least one heating means comprises at least two independently controlled heating zones in the circulating loop.

44. A crystal made by the method of claim 29.
